(19) United States
(12) Patent Application Publication
(10) Pub. No.: US 2005/0285270 A1
(43) Pub. Date: Dec. 29, 2005

(54) Capacitors in semiconductor devices and methods of fabricating the same

(76) Inventor: Jae Suk Lee, Icheon-city (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/157,672

(22) Filed: Jun. 21, 2005

(30) Foreign Application Priority Data
Jun. 24, 2004 (KR) 10-2004-0047524

(51) Int. Cl. H01L 23/48

(52) U.S. Cl. 257/758

(57) ABSTRACT

Capacitors in semiconductor devices and methods of fabricating the same are disclosed. A disclosed capacitor includes a semiconductor substrate, a lower electrode on the semiconductor substrate, a nitride layer on the lower electrode, the nitride layer having an uneven surface formed by isotropic etching and nitridation of silicon nitride, and an upper electrode on the nitride layer.

### FIELD OF THE DISCLOSURE

The present disclosure relates generally to semiconductor devices and, more particularly, to capacitors in semiconductor devices and methods of fabricating the same.

### BACKGROUND

Generally, as the degree of integration of semiconductor devices has increased, many efforts have been made to research and develop a capacitor having sufficient capacitance in a limited area.

There are various known methods of increasing capacitance such as methods of increasing an effective area of a capacitor, methods of forming an ultra thin dielectric layer between two electrodes, methods of forming dielectric layers having a big dielectric constant and the like.

In the effective area increasing method, Ta₂O₅, BST [(Ba,Sr)TiO], PZT[(Pb,La)(Zr,Ti)O] and/or the like can be used as a substance having a high dielectric constant.

However, in employing the high dielectric constant substance, the electrode is formed of an expensive metal such as Pt and/or the like to address the leakage current characteristic. As a result, the fabricating cost is raised.

### BRIEF DESCRIPTION OF THE DRAWINGS

FIG. 1 is a cross-sectional diagram of an example capacitor in an example semiconductor device constructed in accordance with the teachings of the present invention.

FIGS. 2 to 4 are cross-sectional diagrams illustrating an example method of fabricating a semiconductor device performed in accordance with the teachings of the present invention.

Reference will now be made in detail to the examples illustrated in the accompanying drawings. To clarify multiple layers and regions, the thickness of the layers and regions are enlarged in the drawings. Wherever possible, the same reference numbers are used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

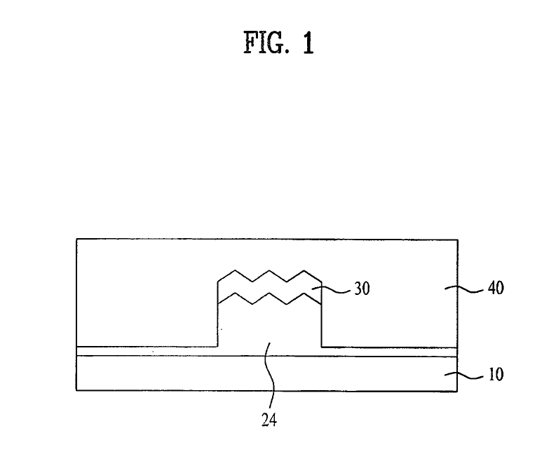

FIG. 1 is a cross-sectional diagram of an example capacitor in an example semiconductor device. In the example of FIG. 1, a lower electrode 10 is formed on a substrate (not shown in the drawing). The substrate includes a semiconductor device (not shown in the drawing), metal lines electrically connected to the semiconductor device and the like. The lower electrode 10 is electrically connected to the semiconductor device or metal lines on the substrate.

A dielectric layer 24 is formed on the lower electrode 10. An upper electrode 30 is formed on the dielectric layer 24. An insulating interlayer 40 is formed on the upper electrode 30.

The dielectric layer 24 is formed of silicon nitride. An upper part of the dielectric layer 24 has an uneven structure. Since the upper electrode 30 is formed along a surface of the uneven structure, a lower surface of the upper electrode 30 contacting the dielectric layer 24 has another uneven structure. The dielectric layer 24 may exist between the insulating interlayer 40 and the substrate in part, which is a leftover from the process of fabricating the capacitor and will be explained in detail later.

Each of the upper and lower electrodes 10 and 30 includes a single layer of Al, Ti and/or the like or may include multi-layers such as Ti/TiN/Al/Ti/TiN, Ta/TaN/Al/Ta/TaN and/or the like with the addition of TiN, TaN and/or the like.

If the dielectric layer 24 has a prominence and/or depression (i.e., an uneven structure) sufficient to increase its surface area, the capacitance of the capacitor is raised. Therefore, without changing the design of an associated semiconductor device or inter-layer structure, the capacitance of the capacitor can be increased with ease.

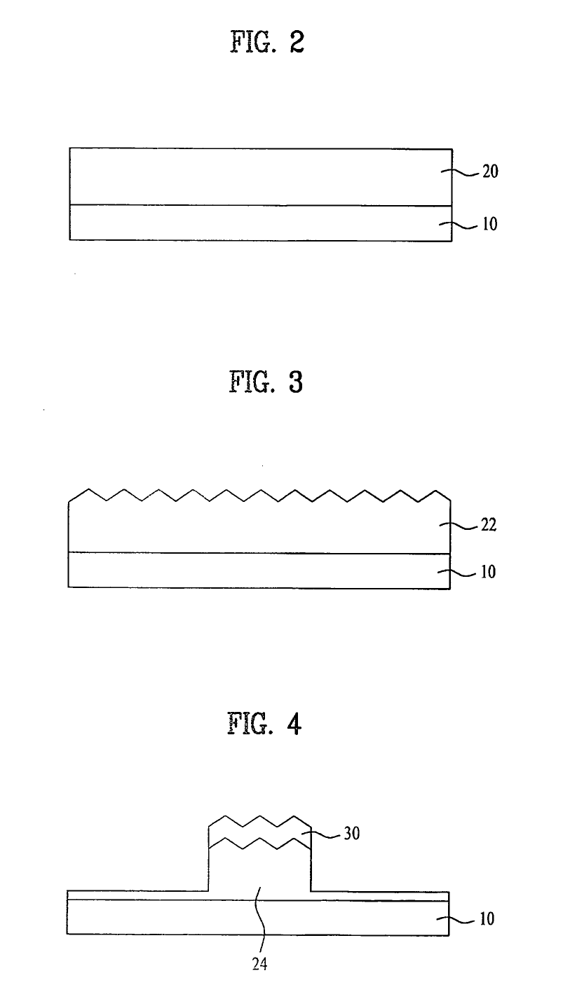

An example method of fabricating a capacitor in a semiconductor device will now be explained with reference to the attached drawings. FIGS. 2 to 4 are cross-sectional diagrams illustrating an example method of fabricating a semiconductor device.

In the example of FIG. 2, a metal layer is formed on a substrate (not shown in the drawing) on which a semiconductor device or metal line is at least partially formed. The metal layer is patterned to form a lower electrode 10. In this case, the metal layer includes a single layer of Al, Ti and/or the like or may include multi-layers such as Ti/TiN/Al/Ti/TiN, Ta/TaN/Al/Ta/TaN and/or the like with the addition of TiN, TaN and/or the like.

A polysilicon layer 20 is formed on the lower electrode 10 by PECVD (plasma enhanced chemical vapor deposition) or the like. The polysilicon layer has (100), (110) and (111) planes according to crystalline growth directions. The polysilicon layer 20 is formed to a thickness of about 100˜1,000 Å at about 350˜400° C.

Referring to FIG. 3, isotropic wet etching is performed on the polysilicon layer 20 to form a jagged surface, including, for example, positions of prominence and depressions, on the surface of the polysilicon layer 20.

An etchant of the wet etch variety is selectively usable according to a layer property of the polysilicon layer 20. For instance, the etchant may include KOH, NaOH or alkali solution of [(KOH or NaOH)+(20˜80 wt % alcohol, TDMAH or the like)]. The etch rate varies according to the crystalline growth direction of the polysilicon layer 20. The etch rate of (100) or (110) plane is faster than that of (111) plane. As a result, the etching forms the projections and depressions on the surface of the polysilicon layer 20.

Subsequently, nitridation is performed on the polysilicon layer 20 by plasma treatment using NH₃ or N₂ gas to form a nitride layer 22. In this example, the nitride layer is formed of silicon nitride of SiₓN_{y}H_{z} and has a different composition ratio, e.g., Si₃N₄ according to the injected gas.

Referring to FIG. 4, a metal layer is formed on the nitride layer 22 and is then selectively etched to form an upper electrode 30 and a dielectric layer 24.

In forming the upper electrode 30 and the dielectric layer 24, a portion of the nitride layer 22 is preferably left to prevent the occurrence of leakage current which would otherwise be generated from the lower electrode 10 whose surface would be damaged by the etchant or etch gas.

Subsequently, an oxide layer, as shown in FIG. 1, is deposited by HDP (high density plasma) and/or the like to cover the upper electrode 30. CMP (chemical mechanical polishing) is then performed on the oxide layer to form an insulating interlayer 40. In the illustrated example, the insulating interlayer 40 is preferably formed to have a thickness of about 5,000˜6,000 Å. Thereafter, a conventional metal line, a conventional protecting layer and/or the like can be formed, if necessary or desired.

From the foregoing, persons of ordinary skill in the art will readily appreciate that the dielectric layer is formed with an uneven structure, thereby facilitating an increase in the capacitance of the capacitor without changing the design or structure of the semiconductor device. Therefore, a semiconductor device of high quality can be manufactured with an enhanced capacitor.

Although the disclosed capacitors and methods are suitable for a wide range of applications, they are particularly well suited for capacitors having a metal/insulator/metal (hereinafter abbreviated MIM) structure.

From the foregoing, persons of ordinary skill in the art will further appreciate that capacitors and methods of fabricating capacitors for use in semiconductor devices have been provided. A disclosed example method of fabricating a capacitor produces a capacitor with increased capacitance.

A disclosed example capacitor includes a lower electrode on the semiconductor substrate, a nitride layer on the lower electrode, the nitride layer having an uneven surface formed by isotropic etching and nitridation of the nitride layer, and an upper electrode on the nitride layer.

Preferably, each of the upper and lower electrodes comprises Ti/TiN/Al/TiN/Ti or Ta/TaN/Al/TaN/Ta.

A disclosed example method of fabricating a capacitor in a semiconductor device comprises forming a lower electrode on a semiconductor substrate, forming a polysilicon layer on the lower electrode, forming a jagged upper surface on the polysilicon layer by isotropic wet etching, forming a nitride layer by nitridating the polysilicon layer, forming a metal layer on the nitride layer, and forming an upper electrode and a dielectric layer by etching the metal and nitride layers selectively.

Preferably, the lower electrode comprises Ti/TiN/Al/TiN/Ti or Ta/TaN/Al/TaN/Ta.

Preferably, the polysilicon layer is nitridated by plasma treatment using NH₃ or N₂ gas.

Preferably, the polysilicon layer is about 100˜1,000 Å thick.

Preferably, the isotropic wet etching is performed with an alkali solution.

More preferably, the alkali solution is selected from the group consisting of KOH, NAOH and [(KOH or NaOH)+(20˜80 wt % alcohol or TDMAH)]. It is noted that this patent claims priority from Korean Patent Application Serial Number P2004-0047524, which was filed on Jun. 24, 2004, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A capacitor in a semiconductor device, comprising:
a semiconductor substrate;
a lower electrode above the semiconductor substrate;
a nitride layer above the lower electrode, the nitride layer having an isotropically etched, uneven surface; and
an upper electrode above the nitride layer.

2. A capacitor as defined in claim 1, wherein each of the upper and lower electrodes comprises Ti/TiN/Al/TiN/Ti or Ta/TaN/Al/TaN/Ta.

3. A method of fabricating a capacitor in a semiconductor device, comprising:
forming a lower electrode above a semiconductor substrate;
forming a polysilicon layer above the lower electrode;
forming a jagged upper surface of the polysilicon layer by isotropic wet etching;
forming a nitride layer by nitridating the polysilicon layer;
forming a metal layer above the nitride layer; and
forming an upper electrode and a dielectric layer by selectively etching the metal and nitride layers.

4. A method as defined in claim 3, wherein the lower electrode comprises Ti/TiN/Al/TiN/Ti or Ta/TaN/Al/TaN/Ta.

5. A method as defined in claim 3, wherein the polysilicon layer is nitridated by plasma treatment using NH₃ or N₂ gas.

6. A method as defined in claim 3, wherein the polysilicon layer is about 100˜1,000 Å thick.

7. A method as defined in claim 3, wherein the isotropic wet etching is performed using an alkali solution.

8. A method as defined in claim 7, wherein the alkali solution is selected from the group consisting of KOH, NAOH and [(KOH or NaOH)+(20˜80 wt % alcohol or TDMAH)].
